(19) United States
(12) Patent Application Publication
(10) Pub. No.: US 2024/0290805 A1
(43) Pub. Date: Aug. 29, 2024

(54) SOLID-STATE IMAGING DEVICE AND ELECTRONIC DEVICE

(71) Applicant: SONY SEMICONDUCTOR SOLUTIONS CORPORATION, KANAGAWA (JP)

(72) Inventors: SHUNSAKU HANAOKA, KUMAMOTO (JP); YUUJI KISHIGAMI, KUMAMOTO (JP); EIICHIROU KISHIDA, KUMAMOTO (JP); AYAKA SEKI, KUMAMOTO (JP); YUJI HARA, KUMAMOTO (JP); SEIGI ONO, KUMAMOTO (JP); JUNKI KOMORI, KUMAMOTO (JP)

(21) Appl. No.: 18/564,966

(22) PCT Filed: Mar. 17, 2022
(86) PCT No.: PCT/JP2022/012124

§ 371 Date: Nov. 28, 2023

(30) Foreign Application Priority Data
Jun. 11, 2021 (JP) 2021-098348

(51) Int. Cl. H01L 27/146

(52) U.S. Cl. CPC H01L 27/14618; H01L 27/14627; H01L 27/14636

(57) ABSTRACT

To provide a solid-state imaging device, by which electrical wiring connection can be made without great difficulty while avoiding problems such as a thermal stress that occurs according to thermal fluctuations resulting from an environmental factor or the like and causes a crack on a cover glass or the like or exfoliation of encapsulating resin. The solid-state imaging device includes: a solid-state imaging element that has a central portion in which an active region for photoelectrically converting incident light is formed, and a circumferential edge portion provided around the central portion; a substrate that has a support on one side and an opening portion formed on an upper portion of the support, the support forming a surrounding space for storing the solid-state imaging element, the solid-state imaging element being mounted in a mounting region at a bottom of the space; a cover glass with a circumferential edge portion on the undersurface of the cover glass, the circumferential edge portion being bonded to the support on one side of the substrate; and a resin sealing portion that provides sealing around the cover glass. The cover glass is integrally sealed by the resin sealing portion, and the encapsulating resin has, on the upper side of the resin sealing portion, a recessed portion toward a bottom of the resin sealing portion, the upper side including the vicinity of the cover glass.

### TECHNICAL FIELD

The present technique relates to a solid-state imaging device and an electronic device provided with the same.

### BACKGROUND ART

In keeping with the recent trend toward downsizing of digital cameras, cellular phones, or onboard cameras and the like, miniaturization is demanded of solid-state imaging devices installed therein. A known solid-state imaging device is configured with, for example, a solid-state imaging element (bare chip) and a cover glass (lid body).

A solid-state imaging element in such a solid-state imaging device has a central portion, in which an active region for converting incident light into charge is formed, and a circumferential edge portion provided around the central portion. Moreover, the cover glass has a base portion facing the active region and side portions bonded to the circumferential edge portion of the solid-state imaging element.

In the manufacturing of such a solid-state imaging device, generally, the sides of the cover glass are bonded to the circumferential edge portion of the solid-state imaging element with an adhesive, and then electrodes disposed outside the circumferential edge portion and wiring conductors are connected by wire bonding.

In a method of manufacturing the solid-state imaging device configured thus, the undersurfaces of the sides of the cover glass are bonded to the circumferential edge portion of the solid-state imaging element, and then the electrodes and the wiring conductors are connected by wire bonding. At this point, in order to prevent the adhesive from sticking to the electrodes,
the electrodes need to be separated from the circumferential edge portion, or
the electrodes need to be upsized to be placed out of the adhesive.

Furthermore, the electrodes need to be placed such that a bonding capillary usable during wire bonding does not interfere with a cover, resulting in upsizing of the solid-state imaging element.

To address the problem, for example, a solid-state imaging device described in PTL 1 is known. Specifically, in the solid-state imaging device, a cover glass is fixed to a solid-state imaging element after wire bonding (connection via wires or the like), thereby preventing a bonding capillary from coming into contact with the cover glass. Even if an adhesive extends onto an electrode pad, the adhesive does not cause any problems because the wires or the like are connected in advance. This eliminate the need for a large distance between the cover glass and the electrode pad, achieving downsizing accordingly.

However, even in the solid-state imaging device formed by the manufacturing method, a large numeric difference in the coefficient of thermal expansion (hereinafter may be referred to as “CTE”) may occur, for example, between encapsulating resin, which is used for attaching the cover glass to a substrate, and the cover glass because of a material difference between organic matter and inorganic matter. Thus, a thermal stress may occur according to thermal fluctuations resulting from an environmental factor or the like and cause a crack on the cover glass or the like or exfoliation of the encapsulating resin.

In a semiconductor device proposed as described in, for example, PTL 2, a through hole portion is provided at the bottom (that is, a semiconductor element mounting surface) of a container-like support with an opened top portion so as to extend along the sides of the element mounting surface. This can reduce a stress during curing of encapsulating resin, thereby avoiding breaking of, for example, an end of the exposed surface of an optically transparent lid body (cover glass).

Specifically, in the semiconductor device described in PTL 2, the bottom internal surface (top surface) of the container-like support including a conductor portion (lead) serves as a die attachment surface. On the die attachment surface, a semiconductor element (optical element) is die-bonded (die-attached) with a die-bonding material (die-attachment material). Moreover, leads on steps on both sides of the die attachment surface and electrode pads on the semiconductor element are wire-bonded by wires or the like.

The upper portion of the die attachment surface, on which the semiconductor element (optical element) is die-bonded, constitutes an opened inner space in the support. A light receiving surface as the top surface of the opened inner space is sealed with a cover glass (lid body). In other words, the cover glass has a circumferential portion that is resin-sealed with an encapsulating resin portion while the top surface of the cover glass is exposed. As an encapsulating resin constituting the encapsulating resin portion, a thermosetting resin or a photo-curable resin is generally used.

A semiconductor device reduced in thickness typically has a structure that fills encapsulating resin around a cover glass. Thus, a stress caused by expansion and shrinkage during curing of the encapsulating resin is applied to the sides (outer periphery) of the cover glass as well as the interface between the encapsulating resin and the support and the interface between the encapsulating resin and the semiconductor element. This may lead to breaking on an end of a surface exposed (exposed surface) on the cover glass in addition to exfoliation between the encapsulating resin and the support or exfoliation between the encapsulating resin and the semiconductor element.

In order to solve such a problem, for example, in the semiconductor device described in PTL 2, an insulating substrate is provided with a resin injection hole that communicates with the inside of a guide ring. However, this configuration cannot avoid breaking on an end of the exposed surface of the cover glass.

To address the problem, for example, a semiconductor device is proposed as described in PTL 3. In the semiconductor device, a through hole portion is provided on a die attachment surface at the bottom of a container-like support with an opened top portion so as to extend along the sides of an element mounting surface. Thus, the semiconductor device is configured with a smaller thickness so as to reduce a stress during curing of encapsulating resin, thereby avoiding breaking of, for example, an end of the exposed surface of a cover glass.

### CITATION LIST

### Patent Literatures

[PTL 1]
JP 2011-165774A
[PTL 2]
JP H8-236738A
[PTL 3]
JP 2008-300462A

### SUMMARY

### Technical Problem

In the semiconductor device described in PTL 3, however, in order to prevent encapsulating resin from leaking from, for example, a bottom-side opening hole of the through hole portion when the resin is injected from the through hole portion, some proactive measures need to be taken, for example, the bottom-side opening hole needs to be closed with, for example, adhesive tape before the injection. In addition, when such adhesive tape is peeled off, the encapsulating resin or the cover glass may be pulled with the tape depending upon the degree of tackiness. Furthermore, at this point, wires or the like contained in the encapsulating resin may be simultaneously pulled to be peeled off from electrodes.

Moreover, in the semiconductor device described in PTL 3, leads formed on the inner surface of the support and the electrode pads of the semiconductor element need to be wire-bonded to be electrically connected to each other in the narrow through hole portion that is circumferentially surrounded, so that the connection is hard to make in the narrow through hole portion and requires high accuracy.

An object of the present technique is to provide a solid-state imaging device and an electronic device provided with the same, by which electrical wiring connection can be made without great difficulty while avoiding problems such as a thermal stress that occurs according to thermal fluctuations resulting from an environmental factor or the like and causes a crack on a cover glass or the like or exfoliation of encapsulating resin.

### Solution to Problem

A solid-state imaging device according to the present technique includes: a solid-state imaging element that has a central portion in which an active region for photoelectrically converting incident light is formed, and a circumferential edge portion provided around the central portion;
a substrate that has a support on one side and an opening portion formed on the upper portion of the support, the support forming a surrounding space for storing the solid-state imaging element, the solid-state imaging element being mounted in a mounting region at the bottom of the space;
a cover glass with a circumferential edge portion on the undersurface of the cover glass, the circumferential edge portion being bonded to the support on one side of the substrate; and
a resin sealing portion that provides sealing around the cover glass;
wherein
the cover glass is integrally sealed by the resin sealing portion, and
the resin sealing portion has, on the upper side of the resin sealing portion, a recessed portion toward the bottom of the resin sealing portion, the upper side including the vicinity of the cover glass.

Another aspect of the solid-state imaging device according to the present disclosure further includes a wire with one end making bonding connection to an electrode provided on the outer periphery of the side of the substrate to electrically connect the solid-state imaging element and the outside, and the recessed portion is formed near the cover glass in a range of a depth without reaching the wire in the resin sealing portion.

Another aspect of the solid-state imaging device according to the present technique, wherein the recessed portion is formed around the vicinity of the circumference of the cover glass in the resin sealing portion.

Another aspect of the solid-state imaging device according to the present technique, wherein the recessed portion is formed on at least one of four sides surrounding the cover glass.

Another aspect of the solid-state imaging device according to the present technique, wherein the recessed portion formed on the at least one side is shaped like a ribbon or a circle in at least one place.

Another aspect of the solid-state imaging device according to the present technique, wherein the recessed portion is formed over an entire area other than the contact portion of the cover glass from the vicinity to the outer periphery of the cover glass.

Another aspect of the solid-state imaging device according to the present technique, wherein the recessed portion is a groove having one of a substantially rectangular shape, a substantially U-shape, and a substantially V-shape in longitudinal section.

Another aspect of the solid-state imaging device according to the present technique, wherein the recessed portion is formed around four sides surrounding the cover glass, and
a lens holder that bears and supports a lens is fixed on an upper portion of the recessed portion.

Another aspect of the solid-state imaging device according to the present technique, wherein the recessed portion is formed in at least multiple places, and the recessed portion in at least one of the multiple places is continuously formed around the four sides surrounding the cover glass, and a lens holder that bears and supports a lens is fixed on an upper portion of the recessed portion continuously formed around the four sides.

Another aspect of the solid-state imaging device according to the present technique, wherein the recessed portion provided on at least one of the four sides surrounding the cover glass is provided with at least one of a highly thermal conductive member, a heat sink, and a Peltier element.

Another aspect of the solid-state imaging device according to the present technique, wherein the resin sealing portion is provided with a second encapsulating resin of a different kind from the encapsulating resin in addition to the resin sealing portion while the second sealing resin covers the resin sealing portion, and the recessed portion is formed with a depth reaching the encapsulating resin under the second encapsulating resin.

An electronic device according to the present technique includes a solid-state imaging device including: a solid-state imaging element that has a central portion in which an active region for photoelectrically converting incident light is formed, and a circumferential edge portion provided around the central portion;
a substrate that has a support on one side and an opening portion formed on the upper portion of the support, the support forming a surrounding space for storing the solid-state imaging element, the solid-state imaging element being mounted in a mounting region at the bottom of the space;
a wire with one end making bonding connection to an electrode provided on the outer periphery of the side of the substrate to electrically connect the solid-state imaging element and the outside, and
a cover glass having an outside shape like one of a rectangle, a square, and a circle with a circumferential edge portion on the undersurface of the cover glass, the circumferential edge portion being bonded to one side of the substrate; and
a resin sealing portion that provides sealing around the cover glass;
wherein
the cover glass is integrally sealed for the wire with the encapsulating resin, and the encapsulating resin has a recessed portion on the upper side of the encapsulating resin in a range of a depth without reaching the wire, the upper side including the vicinity of the cover glass.

### Advantageous Effects of Invention

The present technique allows wiring connection between the solid-state imaging element and the substrate by wire bonding in a wide area. This enhances the ease of wiring, facilitating the manufacturing of the solid-state imaging device, accordingly. Additionally, according to the present technique, a recessed portion is formed on the upper side including the vicinity of the cover glass in the encapsulating resin that provides sealing around the cover glass while the circumferential edge portion of the undersurface of the cover glass is bonded to one side of the substrate. Thus, even if a difference in the coefficient of linear expansion is large between the cover glass and the encapsulating resin, the present technique can provide a reliable solid-state imaging device and a reliable electronic device provided with the solid-state imaging device, which can suppress problems such as a thermal stress that occurs according to thermal fluctuations and causes a crack on the cover glass or the like or exfoliation of encapsulating resin.

### BRIEF DESCRIPTION OF DRAWINGS

FIG. 1 is a perspective view illustrating the configuration of a solid-state imaging device according to a first embodiment of the present technique.

FIG. 2A is a plan view illustrating the configuration of the solid-state imaging device according to the first embodiment of the present disclosure, and FIG. 2B is a cross-sectional view.

FIG. 3 is a perspective view illustrating a mold frame for manufacturing a resin sealing portion including a slit that is a recessed portion of the solid-state imaging device according to the present technique.

FIGS. 4A to 4C are cross-sectional views illustrating the bottom shapes of various slits that are recessed portions of the solid-state imaging device according to the present technique.

FIG. 5A is a plan view illustrating the configuration of a solid-state imaging device according to a second embodiment of the present disclosure, and FIG. 5B is a cross-sectional view of FIG. 5A.

FIG. 6A is a plan view illustrating the configuration of a solid-state imaging device according to a third embodiment of the present disclosure, and FIG. 6B is a cross-sectional view of FIG. 6A.

FIG. 7A is a plan view illustrating the configuration of a solid-state imaging device according to a fourth embodiment of the present disclosure, and FIG. 7B is a cross-sectional view of FIG. 7A.

FIG. 8A is a plan view illustrating the configuration of a solid-state imaging device according to a fifth embodiment of the present disclosure, and FIG. 8B is a cross-sectional view of FIG. 8A.

FIG. 9A is a plan view illustrating the configuration of a solid-state imaging device according to a sixth embodiment of the present disclosure, and FIG. 9B is a cross-sectional view of FIG. 9A.

FIG. 10 is an explanatory drawing showing the operation/working effect of the solid-state imaging device according to the six embodiment in FIG. 9.

FIG. 11A is a plan view illustrating a modification example of the solid-state imaging device according to the sixth embodiment of the present disclosure, and FIG. 11B is a cross-sectional view of FIG. 11A.

FIG. 12 is a cross-sectional view illustrating the configuration of a solid-state imaging device according to a seventh embodiment of the present disclosure.

FIG. 13A is a plan view illustrating the configuration of a solid-state imaging device according to an eighth embodiment of the present disclosure, and FIG. 13B is a cross-sectional view of FIG. 13A.

FIG. 14 is an explanatory drawing illustrating the layout of a second slit of the solid-state imaging device according to the eighth embodiment of the present technique.

FIG. 15 is a cross-sectional view illustrating the configuration of a solid-state imaging device according to a ninth embodiment of the present disclosure.

FIG. 16 is a block diagram illustrating a lattice pattern of an electronic device provided with the solid-state imaging device according to the present technique.

### DESCRIPTION OF EMBODIMENTS

The present technique is provided to avoid problems such as a crack on a cover glass and exfoliation of encapsulating resin by suppressing an amount of thermal expansion and a thermal stress by reducing the contact length (amount) of a resin sealing portion with the cover glass, the contact length being reduced by forming a recessed portion on the upper side including the vicinity of the cover glass in the resin sealing portion that provides sealing around the cover glass while the circumferential edge portion of the undersurface of the cover glass is bonded to one side of a substrate.

Modes for carrying out the present technique (hereinafter referred to as “embodiments”) will be described below with reference to the drawings. The description of embodiments will be made in the following order.

1. Solid-state Imaging Device according to First Embodiment

2. Modification Example of Solid-state Imaging Device according to First Embodiment (Modification Example of Recessed Portion)

3. Solid-state Imaging Device according to Second Embodiment

4. Solid-state Imaging Device according to Third Embodiment

5. Solid-state Imaging Device according to Fourth Embodiment

6. Solid-State Imaging Device according to Fifth Embodiment

7. Solid-State Imaging Device according to Sixth Embodiment

8. Modification Example of Solid-state Imaging Device according to Sixth Embodiment (Modification Example of Cover Glass Layout)

9. Solid-State Imaging Device according to Seventh Embodiment

10. Solid-State Imaging Device according to Eighth Embodiment

11. Solid-State Imaging Device according to Ninth Embodiment

12. Configuration Example of Electronic Device

### <Configuration Example of Solid-State Imaging Device According to First Embodiment>

A configuration example of a solid-state imaging device 1A according to a first embodiment of the present technique will be specifically described below with reference to the accompanying drawings.

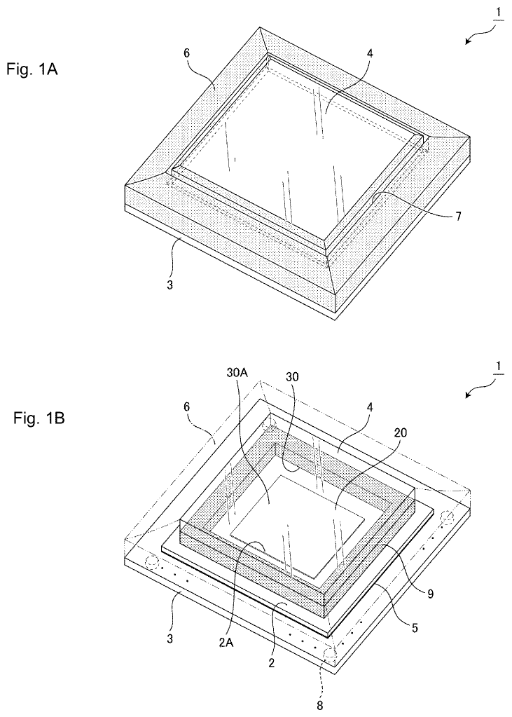

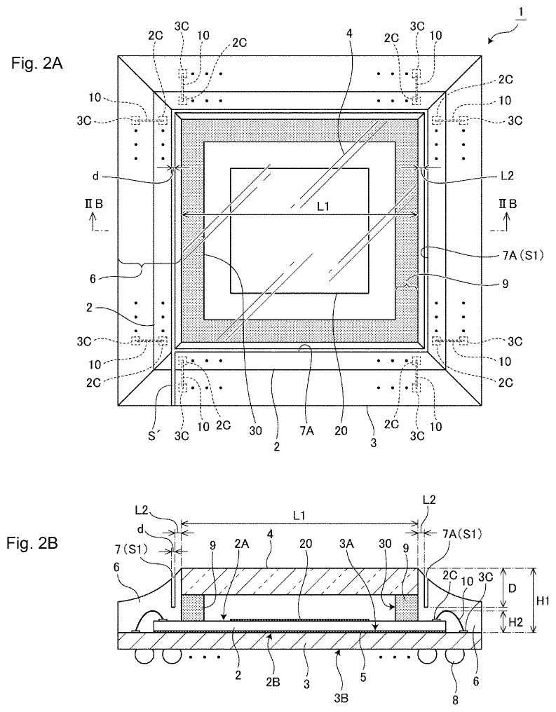

FIGS. 1 and 2 illustrate the first embodiment of the present technique. The solid-state imaging device 1A according to the first embodiment includes an image sensor 2 serving as a solid-state imaging element, a substrate 3 on which the image sensor 2 is die-bonded with a die-bonding material 5, a cover glass 4 serving as a translucent member that is bonded and supported by cover-glass adhesive resin (hereinafter referred to as “adhesive resin portion 9”) on the substrate 3, the die-bonding material 5 that fixes the image sensor 2 onto the substrate 3, a resin sealing portion 6, a recessed portion 7 (see FIG. 2) provided on the resin sealing portion 6, and solder balls 8 used for connecting the substrate 3 and the outside. In FIG. 1, the cover glass 4 is indicated by chain double-dashed lines for convenience. In FIGS. 1 and 2A, the illustration of various wirings and pad electrodes is omitted to facilitate the understanding of the structure.

The solid-state imaging device 1A may have a so-called flip-flop structure in which, for example, the image sensor 2 and the substrate 3 are electrically connected to each other via a plurality of metallic bumps. The solid-state imaging device 1 has a package structure in which the cover glass 4 is mounted near a front side 3A of the substrate 3 so as to cover an opening portion 30 with the image sensor 2 die-bonded on the front side 3A and an enclosed space (hereinafter may be referred to as “cavity 30A”) including the space of the opening portion 30 of the substrate 3 is provided between the image sensor 2 and the cover glass 4.

The image sensor 2 includes a semiconductor substrate made of silicon (Si), which is an example of a semiconductor. One side (the upper side in FIG. 1) of the semiconductor substrate substantially shaped like a rectangular plate serves as a light receiving side that receives external light. The image sensor 2 is an individual chip shaped like a rectangular plate with the light receiving side denoted as a front side 2A and the opposite side denoted as a back side 2B. The image sensor 2 according to the present embodiment is a CMOS (Complementary Metal Oxide Semiconductor) image sensor. The image sensor 2 may be a CCD (Charge Coupled Device) image sensor.

The image sensor 2 is formed on the semiconductor substrate. In a central portion on the front side 2A, an active region including multiple pixels is formed to photoelectrically convert incident light. Specifically, the image sensor 2 has a pixel part 20 as a light receiving part in the central portion on the front side 2A and a boundary region around the pixel part 20. The pixel part 20 is a light receiving region including multiple pixels formed in a predetermined layout, for example, a Bayer layout. The pixel part 20 includes an effective pixel region that generates signal charge, amplifies the signal charge, and reads the signal charge by photoelectric conversion in each pixel.

The pixels of the pixel part 20 each include a photodiode serving as a photoelectric conversion unit having a photoelectric conversion function and a plurality of pixel transistors. The photodiode has a light receiving surface for receiving incident light from the front side 2A of the image sensor 2 and generates signal charge according to the amount (intensity) of light incident on the light receiving surface. The plurality of pixel transistors includes, for example, MOS (Metal Oxide Semiconductor) transistors provided respectively for the amplification, transfer, selection, and reset of the signal charge generated by the photodiode. The plurality of pixels may have a shared pixel structure in which photodiodes and transfer transistors constituting a plurality of unit pixels are configured to share another pixel transistor.

Near the front side 2A of the image sensor 2, an antireflective film including an oxide film or a flattened film made of an organic material is provided for a predetermined substrate and a color filter and an on-chip lens (OCL) or the like are provided for each pixel. The films, filter, and lens are not illustrated. In the image sensor 2 configured thus, external light incident on the on-chip lens passes through the color filter and the flattened film or the like and is received by the photodiode.

The image sensor 2 is configured as, for example, a front side illumination sensor in which the pixel part 2A is formed on the front side of the semiconductor substrate, a back side illumination sensor in which a photodiode or the like is inverted to improve the transmittance of light and the back side of the semiconductor substrate is placed as a light receiving side, or a chip in which the peripheral circuits of pixels are stacked. However, the image sensor 2 according to the present technique is not limited to these configurations.

As illustrated in FIG. 2, in order to electrically connect the central pixel part 20 and pad electrodes 2C around the pixel part 20, the image sensor 2 according to the present embodiment has, for example, pattern wiring in a predetermined pattern on the front side 2A. The pattern wiring is not illustrated. Moreover, wires 10 made of appropriate metals such as gold, copper, and aluminum are formed by a wire bonder or the like on the pad electrodes 2C on the peripheral side of the image sensor 2 and between the pad electrodes 2C on the image sensor 2 and pad electrodes 3C provided on the front side 3A of the substrate 3 on which the image sensor 2 is mounted. The pad electrodes 3C will be described later.

The entire substrate 3 has an outside shape like a rectangular plate and includes the front side 3A as one plate surface and a back side 3B as the other plate surface opposite to the front side 3A. On the substrate 3, the image sensor 2 is mounted on the front side 3A with the die-bonding material 5 by a die bonder.

Furthermore, the opening portion 30 for passing light to be received by the pixel part 2A of the image sensor 2 is provided near the front side 3A of the substrate 2. The substrate 3 is formed by providing a wiring layer and electrodes on a substrate made of, for example, organic materials such as plastic or inorganic materials such as ceramic.

The substrate 3 is configured like a parallel plate type and has the opening portion 30 in a central portion on the front side 3A on which the image sensor 2 is die-bonded. The opening portion 30 is configured as a substantially rectangular inner space corresponding to the rectangular outside shape of the substrate 3 in plan view, that is, as the cavity 30A.

For the substrate 3 configured thus, the image sensor 2 is provided on the front side 3A of the substrate 3 such that the light receiving surface faces the opening space of the opening portion 30. The image sensor 2 has larger outside dimensions than the opening portion 30 of the substrate 3 and is provided to largely occupy the opening face of the substrate 3.

The cover glass 4 is an example of a transparent member having a parallel plate shape and is a rectangular plate member smaller than the substrate 3. On the light receiving side of the image sensor 2, the cover glass 4 provided above the substrate 3 is parallel to the image sensor 2 and is disposed at a certain distance from the image sensor 2. The cover glass 4 is fixed with proper adhesive resin 9 with respect to the front side 3A of the substrate 3.

The cover glass 4 has outside dimensions larger than the opening dimensions of the opening portion 30 of the substrate 3 and is provided to cover the opening portion 30 from the upper side. Thus, the cover glass 4 is provided above the image sensor 2 so as to face the front side 2A of the image sensor 2 through the opening portion 30 of the substrate 3. The cover glass 4 can be made up of proper inorganic materials, for example, inorganic materials including silicon dioxide (SiO2) as a chief material.

Therefore, the coefficient of thermal expansion (CTE), for example, the coefficient of linear expansion (hereinafter referred to as “α₁”) is generally smaller than the coefficient of linear expansion (hereinafter referred to as “α₂”) of encapsulating resin as a material of the resin sealing portion 6, that is, the resin sealing portion 6 made of an organic material. The resin sealing portion 6 will be described later.

The cover glass 4 typically transmits various kinds of light entering from an optical system including a lens located above the cover glass 4 and conveys the light to the light receiving surface of the image sensor 2 through the cavity 30. The cover glass 4 has the function of protecting the light receiving surface of the image sensor 2 and the function of blocking the entry of external moisture (water vapor) and dust or the like into the cavity 30 in cooperation with the substrate 3 and the adhesive resin 9. The cover glass 4 may be replaced with, for example, a plastic plate or a silicon plate that only transmits infrared light.

The die-bonding material 5 is an adhesive for fixing the image sensor 2 to the substrate 3. The die-bonding material 5 may be identical to or different from encapsulating resin that is a material of the resin sealing portion 6. Specifically, as an adhesive for fixing the image sensor 2 to the substrate 3, for example, solder or die-bonding resin paste (Ag epoxy, Ag polyimide) can be used. In the present embodiment, the image sensor 2 is fixed by a die bonder using die-bonding resin paste different from the encapsulating resin used for the resin sealing portion 6. The coefficient of linear expansion of the resin paste for the die-bonding material 5 of the present embodiment will be referred to as “α₃.”

The resin sealing portion 6 seals the outer periphery of the cover glass 4 mounted on the front side 2A of the image sensor 2 with the adhesive resin 9, thereby blocking the entry of external dirt and dust or moisture or the like into the cavity 30A in the opening portion 30. The resin sealing portion 6 is formed along the outer periphery of the cover glass 4 and has a predetermined width dimension and substantially the same outside shape as the cover glass 4. The resin sealing portion 6 is formed around the pixel part 20 occupying the central portion of the image sensor 2.

As the encapsulating resin used for the resin sealing portion 6, a proper organic resin material can be used. As the encapsulating resin used for the resin sealing portion 6 of the present embodiment, for example, an epoxy material, an acrylic material, a silicone material, mold resin, or an organic material prepared by combining any of these materials can be used.

Since the encapsulating resin used for the resin sealing portion 6 is an organic material, the coefficient of linear expansion (α₂) is generally larger than the coefficient of linear expansion (α₁) of the cover glass 4 made of an inorganic material as expressed below.

$${α}_{2} ≫ {α}_{1} \qquad ( 1 )$$

The bottom (undersurface) of the resin sealing portion 6 may be integrally bonded with the encapsulating resin such that the bottom is disposed between the pixel part 20 and a wiring part (pattern wiring), which is not illustrated, on the outer edge side of the image sensor 2, in other words, the bottom contains the pattern wiring from the upper side of the pattern wiring. As illustrated in FIG. 2, the pad electrodes 2C are provided in the leading end portion (that is, a circumferential edge side on the image sensor 2) of the pattern wiring of the wiring part integrally sealed with the resin sealing portion 6, whereas the pad electrodes 3C are provided on a circumferential edge side on the substrate 3. The pad electrodes 2C and the pad electrodes 3C are electrically connected by the arch-shaped bonding connections of gold wires, copper wires, and other wires 10. In this configuration, the maximum height of the wires 10 from the front side 3A of the substrate 3 is denoted as a height H2 as shown in B of FIG. 2.

The recessed portion 7 prevents problems such as exfoliation or a crack on the cover glass 4. Such problems are caused by a thermal stress generated by a large difference in the amount of extension between the cover glass 4 and the encapsulating resin, the difference being made by a difference between the coefficient of linear expansion (α₁) of the cover glass 4 and the coefficient of linear expansion (α₂) of the encapsulating resin, which is a material of the resin sealing portion 6, according to a temperature change under the installation environment of the solid-state imaging device 1. The recessed portion 7 of the present embodiment is configured with a slit S1 of the resin sealing portion 6 that is a source of a stress. The slit S1 having a groove width d is provided along the outer periphery of the cover glass 4.

The slit S1 constituting the recessed portion 7 is formed to satisfy the following expression:

$$D < {H}_{1} - H 2 \qquad ( 2 )$$

where H₁ is a length from the front side 3A of the substrate 3 to the top surface of the cover glass 4, and
H₂ is a length from the front side 3A of the substrate 3 to the top of the wire 10.

In order to quickly suppress the amount of linear expansion in, in particular, a contact portion of the encapsulating resin of the resin sealing portion 6 with the cover glass 4, the slit S1 constituting the recessed portion 7 needs to be provided as close as possible to the outer periphery of the cover glass 4. As described above, the resin sealing portion 6 needs to be provided around the outer periphery of the cover glass 4 in order to prevent the entry of, for example, dust or moisture from the periphery of the cover glass 4. Under such circumstances, the slit S1 is preferably formed in a proper layout without excessively approaching the cover glass 4. The slit S1 of the present embodiment preferably has a maximum width dmax equal to or smaller than, for example, 0.01 mm as expressed below.

$$d max \leq 0.01 mm \qquad ( 3 )$$

The method of forming the slit S1 can be, for example, blade dicing or laser dicing. As a method of providing the slit S1, for example, a mold frame 50 may be formed like the resin sealing portion 6 in a predetermined shape and may be filled with the encapsulating resin.

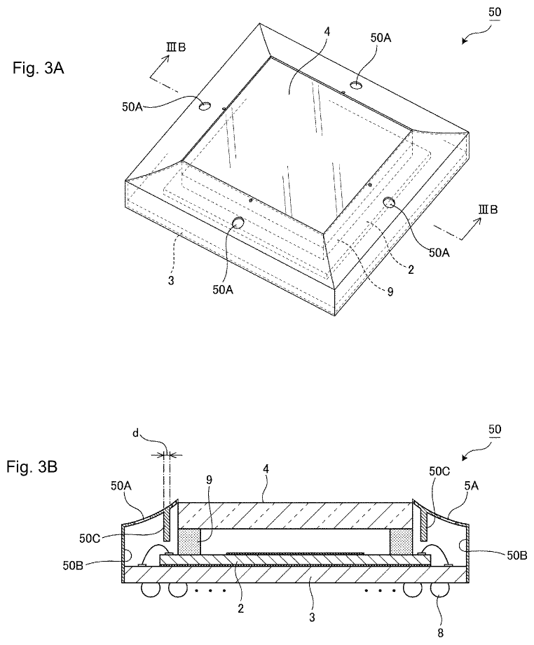

Specifically, for example, the mold frame 50 is fit onto the cover glass 4 as illustrated in FIG. 3 and thus may have a structure in which fitting holes 50A are provided on the upper side of a cavity 50B and a protrusion 50C having a thickness d (the slit S1 after the mold frame 50 is removed) is circumferentially suspended downward from a tilted ceiling surface inside the cavity 50B. After a proper parting agent is applied to the inner surface of the mold frame 50, the mold frame 50 is placed in alignment with the outer periphery of the front side 2A of the image sensor 2 and the outer periphery of the front side 3A of the substrate 3 having the wire-bonded wires 10 such that the cavity 50B is placed around the cover glass 4 from the opened undersurface of the mold frame 50. In this state, the mold frame 50 is firmly fixed and set, and then liquid encapsulating resin is injected into the mold frame 50 from injection holes 50B and is hardened therein. The resin sealing portion 6 with the slit S1 may be formed thus.

In the present embodiment, for example, the slit S1 provided along the outer periphery of the cover glass 4 has an extended portion S′ that is partially extended to the outer periphery of the solid-state imaging device 1 as illustrated in A of FIG. 2. The provision of the extended portion S′ is not always necessary.

Metallic bumps 8 are provided to electrically connect the back side 3B of the substrate 3 and an external secondary substrate, which is not illustrated. The substrate 3 and the secondary substrate, which is not illustrated, are electrically connected to each other via the metallic bumps 8. The metallic bumps 6 are protruding terminals constituting a flip-chip structure that electrically connects, for example, the wiring layer formed on the back side 3B of the substrate 3 and electrodes formed on the front side of the external secondary substrate, which is not illustrated.

For example, the metallic bumps 8 spaced at predetermined intervals in an array are provided around the opening portion 4 as many as the number of electrodes formed on the front side 2a of the mage sensor 2. The metallic bumps 6 include, for example, Au stud bumps, solder ball bumps, and Au—Ag alloy bumps.

The adhesive resin 9 constitutes the support for forming a surrounding space that stores the image sensor 2 as a solid-state imaging element. An epoxy material, an acrylic material, a silicone material, or a hybrid material thereof may be used as the adhesive resin 9. Alternatively, a photosensitive resin may be used as the adhesive resin 9.

In the solid-state imaging device 1 configured thus, light having passed through glass 5 is detected after being received by a light receiving element, which constitutes a pixel disposed in the pixel part 20 of the image sensor 2, through the cavity 30A.

In the solid-state imaging device 1 configured thus, the slit S1 constituting the recessed portion 7 provided on the resin sealing portion 6 is formed along and near the outer periphery of the cover glass 4. Thus, even in an installation environment susceptible to an ambient temperature change, in other words, even if the temperature change causes a large difference in coefficient of linear expansion between the cover glass 4 and the encapsulating resin portion 6, a generated thermal stress (F) can be considerably reduced because of a small distance L between the cover glass 4 and the slit S1.

Specifically, for the encapsulating resin constituting the resin sealing portion 6 and glass constituting the cover glass 4, typically, an extension amount ΔX is uniquely determined by equations below according to an increase in temperature (T). In this case, it is assumed that both ends of the encapsulating resin and glass freely expand without being restricted.

### 1) Glass:

$$Extension amount ( Δ {X}_{1} ) = {L}_{1} \cdot Δ T \cdot {α}_{1} \qquad ( 4 )$$

L₁: the length of a long side of the cover glass 4

ΔT: a temperature increase

α₁: a coefficient of linear expansion

### 2) Encapsulating Resin:

$$Extension amount ( Δ {X}_{2} ) = {L}_{2} \cdot Δ T \cdot {α}_{2} \qquad ( 5 )$$

L₂: the length of the resin sealing portion from the outer periphery of the cover glass to the slit

ΔT: a temperature increase

α₂: a coefficient of linear expansion

In these equations, parameters are limited as follows:

The coefficients of linear expansion are expressed as α₁<α₂, and the length L is expressed as L₁>>L₂.

Thus, depending upon a difference between the coefficients of linear expansion α₁ and α₂,

for example, (8.5 to 9)×10⁻⁶/° C. is set for plate glass, and

(2 to 4)×10⁻⁵//° C. is set for epoxy resin.

This obtains ΔX₁˜ΔX₂, that is, the extension amounts are approximately equal to each other.

Therefore, the extension amount ΔX₁ of the cover glass 4 and the extension amount ΔX₂ of the encapsulating resin from the slit S1 of the resin sealing portion 6 to the cover glass 4 are not considerably different from each other, causing thermal stresses generated by the thermal expansion of the encapsulating resin and the cover glass to substantially cancel each other out. The same is applied to thermal shrinkage as in the description of thermal expansion.

Hence, the solid-state imaging device 1A according to the present embodiment can effectively suppress the generation of a thermal stress caused by thermal fluctuations. This can effectively avoid problems such as a crack on the cover glass 4 and exfoliation between the adhesive resin portion 9 and the encapsulating resin portion 6. Furthermore, the solid-state imaging device 1A according to the present embodiment allows wiring connection between the pad electrodes 2C on the image sensor 2 and the pad electrodes 3C on the substrate 3 by wire bonding in a wide area on the front side of the substrate 3. This enhances the ease of wiring, facilitating the manufacturing of the solid-state imaging device 1A, accordingly.

### <2. Modification Example of Solid-State Imaging Device According to First Embodiment>

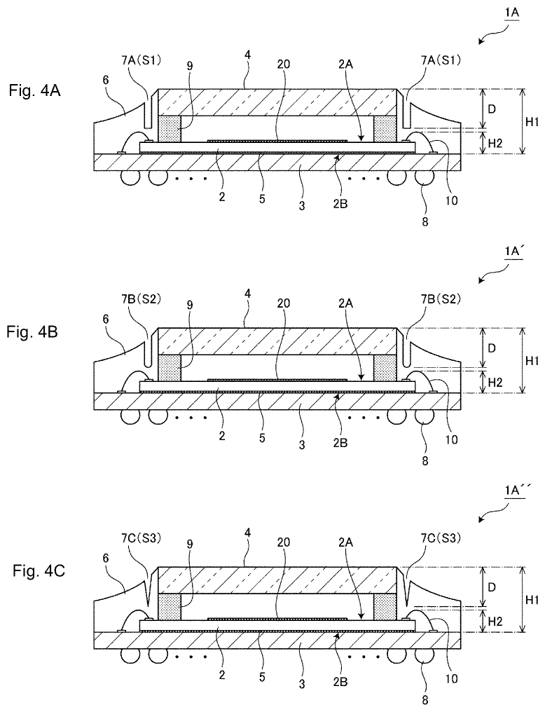

Referring to FIG. 4, a modification example of the solid-state imaging device 1A according to the first embodiment of the present technique will be described below.

The cross-sectional shape of the recessed portion 7 of the present embodiment is not limited to the substantially rectangular shape of a longitudinal section constituting the recessed portion 7 of the solid-state imaging device 1 according to the first embodiment in A of FIG. 4, in other words, the slit S1 shaped like a narrow groove having a flat bottom. Additionally, for example, in a solid-state imaging device 1A′ according to a first modification example illustrated in B of FIG. 4, the longitudinal section of a slit S2 constituting a recessed portion 7B may be substantially U-shaped. As in the first embodiment, the slit S2 is configured with a depth D that does not reach the top of the wire 10.

Furthermore, for example, in a solid-state imaging device 1A″ according to a second modification example illustrated in C of FIG. 4, the section of a slit S3 constituting a recessed portion 7C may be substantially V-shaped. As in the first modification example, the slit S3 is configured with a depth that does not reach the top of the wire 10.

Thus, the recessed portion 7B and the recessed portion 7C that include the slits of the modification examples can be configured in various types, achieving extensive use of the manufacturing method.

### <3. Solid-State Imaging Device According to Second Embodiment>

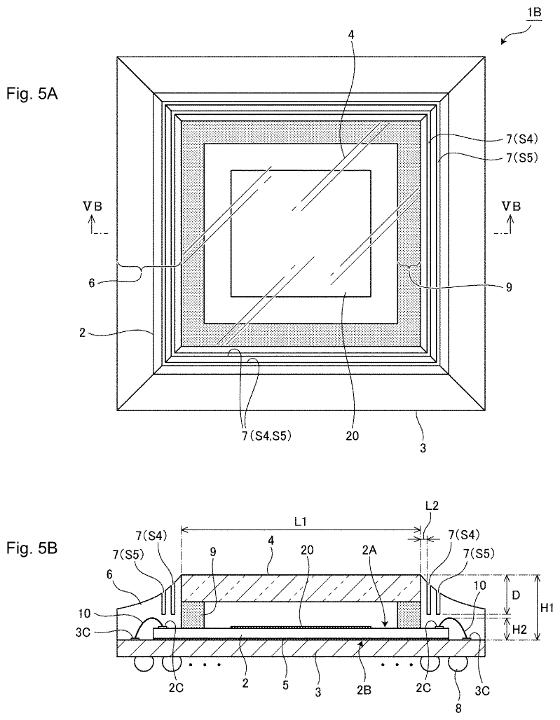

Referring to FIG. 5, a solid-state imaging device 1B according to a second embodiment of the present technique will be specifically described below. In the present embodiment, the same parts as those of the first embodiment are denoted by the same reference numerals, and repeated descriptions thereof are omitted.

The solid-state imaging element 1B of the present embodiment in FIG. 5 is different from the solid-state imaging element 1A of the first embodiment in the formation of dual slits constituting a recessed portion 7.

The recessed portion of the present embodiment includes a first slit S4 and a second slit S5. In this configuration, the first slit S4 can be formed with the same structure at the same position in a resin sealing portion 6 as the slit S of the first embodiment.

The second slit S5 is formed outside the first slit S4. The second slit S5 can be configured with a narrow groove having the same width as the first slit S4. The second slit S5 has a depth D that does not reach the top of a wire 7. The first slit S4 also has the depth D.

The first and second slits S4 and S5 of the present embodiment can be formed by the same method as the first embodiment.

Thus, according to the present embodiment, the provision of the first and second slits S4 and S5 can further reduce a thermal stress applied to a cover glass 4 or the like by the resin sealing portion 6 according to thermal fluctuations, thereby achieving the reliable solid-state imaging device 1B even in use under an environment where thermal fluctuations are larger.

### <4. Solid-State Imaging Device According to Third Embodiment>

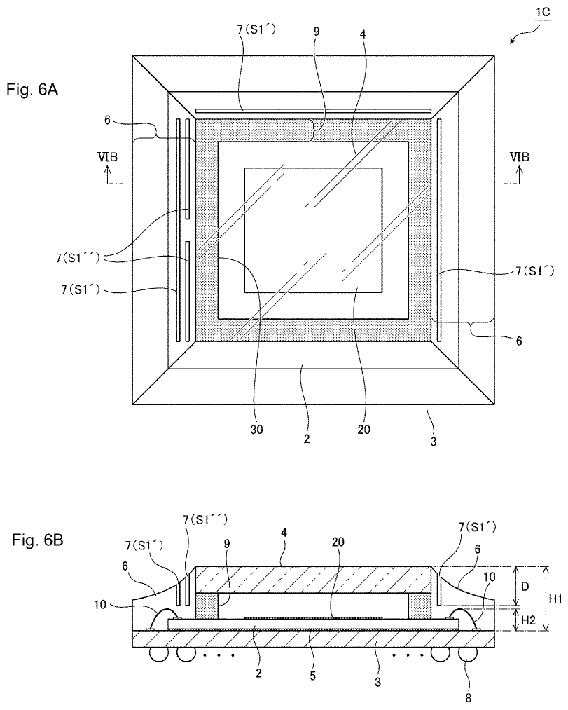

Referring to FIG. 6, a solid-state imaging device 1C according to a third embodiment of the present technique will be specifically described below. In the present embodiment, the same parts as those of the first embodiment are denoted by the same reference numerals, and repeated descriptions thereof are omitted.

In the solid-state imaging device 1C illustrated in FIG. 6, a recessed portion 7 may be formed in various shapes formed along each side of the outer periphery of a cover glass 4 and an adhesive resin portion 9 that fixes the cover glass 4 to the front side of an image sensor 2, instead of the substantially square shape of the recessed portion 7 in plan view in the solid-state imaging devices of the first and second embodiments.

For example, a slit S1′ like a long and narrow groove may be provided along each of an outer surface on a long side constituting the upper and lower outer peripheries of the cover glass 4 and the adhesive resin portion 9 and an outer surface on a short side constituting the left and right outer peripheries while being located as close as possible to the outer surface.

Moreover, in the present embodiment, two separate slits S1″ like short and narrow grooves may be provided along an outer surface on the short side constituting the left and right outer peripheries of the cover glass 4 and the adhesive resin portion 9.

The recessed 7 portion of the present embodiment may be configured such that the slit S1′ like a long and narrow groove is provided in parallel with and outside the slits S1″ like short and narrow grooves. Moreover, for example, three or more slits S1′ like long and narrow grooves (or slits S1″ like short and narrow grooves), which are not illustrated, may be provided close to one another in parallel.

The cover glass 4 and the adhesive resin portion 9 in the present embodiment are substantially shaped like rectangles having short sides on the left and right and longs sides on the top and bottom. For example, the slits may be formed in a square shape with all sides having the same length on the top and bottom and left and right. In the present technique, for example, even if the cover glass and the adhesive resin portion are perfect circles or ellipses instead of rectangles, slits can be similarly formed in various shapes near the cover glass and the adhesive resin portion.

### <5. Solid-State Imaging Device According to Fourth Embodiment>

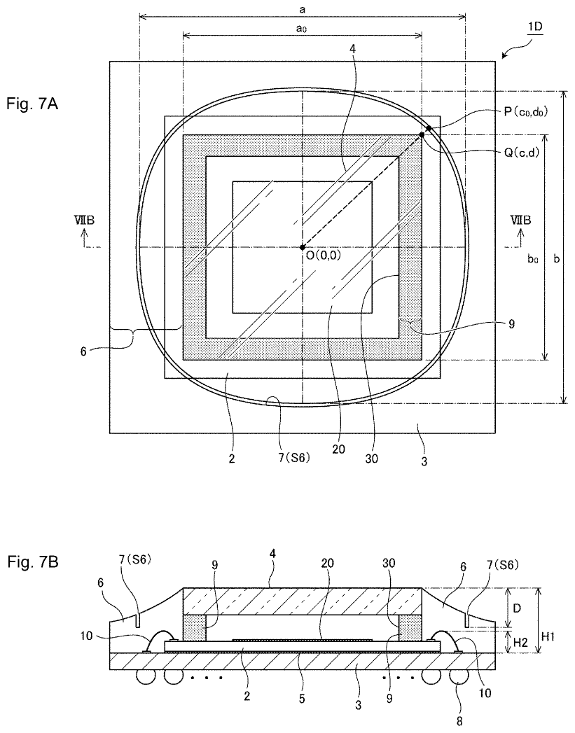

Referring to FIG. 7, a solid-state imaging device 1D according to a fourth embodiment of the present technique will be specifically described below. In the present embodiment, the same parts as those of the first embodiment are denoted by the same reference numerals, and repeated descriptions thereof are omitted.

The solid-state imaging element 1D of the present embodiment in FIG. 7 is different from the solid-state imaging element 1A of the first embodiment in that a slit S6 constituting a recessed portion 7 is oval-like in shape.

The slit S6 shaped like a horizontally extended ellipse in plan view in the present embodiment may be a perfect circle or the like. For example, if the slit S6 is oval, an elliptic equation that determines the shape of the slit S6 at cartesian coordinates (X, Y) with an origin point O is expressed as follows:

$${[ X / ( a / 2 ) ]}^{2} + {[ Y / ( b / 2 ) ]}^{2} = 1$$

where a is a length on a major axis, and
b is a length on a minor axis.

In this configuration, as illustrated in A of FIG. 7, the oval slit S6 needs to be located outside a cover glass 4 and a resin adhesive portion 9 having the same shape as the cover glass and thus needs to satisfy at least the following conditions:

$$a > {a}_{0} \qquad ( 6 )$$

$$b > {b}_{0} \qquad ( 7 )$$

where a₀ is the length of a long side of the cover glass and the resin adhesive portion, and
b₀ is the length of a short side of the cover glass and the resin adhesive portion.

Furthermore, when the oval slit S6 is close to the cover glass 4 and the resin adhesive portion 9 having the same shape as the cover glass, P(c₀, d₀) represents the coordinates of a point at the upper left corner of the cover glass 4 and the resin adhesive portion 9 having the same shape as the cover glass and Q(c, d) represents the coordinates of a closest point of the slit S6 to the cover glass and the resin adhesive portion. The conditions are expressed as below.

$$c > {c}_{0} \qquad ( 8 )$$

$$d > {d}_{0} \qquad ( 9 )$$

where point Q satisfies an elliptic equation and thus the following condition is obtained.

$${( 2 c / a )}^{2} + {( 2 d / b )}^{2} = 1 \qquad ( 10 )$$

As is evident from the description, lengths a and b of the major axis and minor axis of the slit S6 need to satisfy all the conditions (6) to (10).

Therefore, according to the present embodiment, when an external force is applied to, for example, the solid-state imaging device 1D, the slit S6 oval-shaped in plan view can effectively avoid a stress concentration caused by the external force applied to any portion on the circumference of the slit S6. In other words, the occurrence of a break or a crack from the slit S6 can be effectively avoided, thereby improving the durability and reliability, accordingly.

If the oval slit S6 serving as the recessed portion 7 of the present embodiment is replaced with a slit like a perfect circle in plan view, an external force can be uniformly received at any point on the circumference. This can further avoid the occurrence of a break or a crack, achieving higher durability and reliability.

### <6. Solid-State Imaging Device According to Fifth Embodiment>

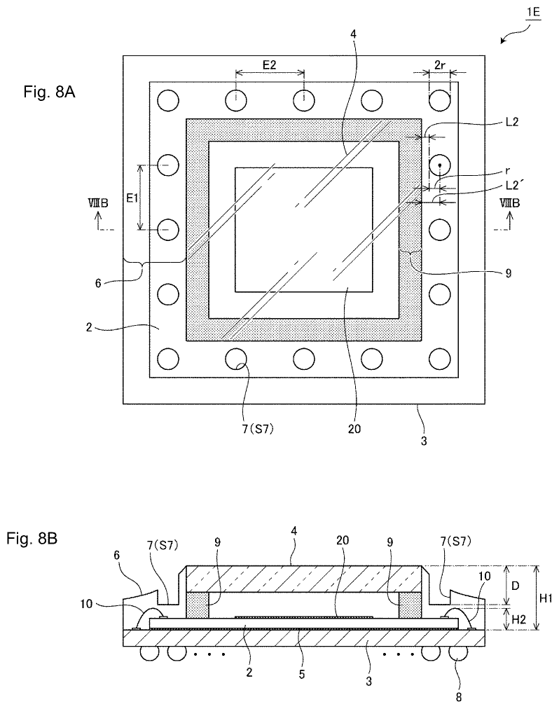

Referring to FIG. 8, a solid-state imaging device 1E according to a fifth embodiment of the present technique will be specifically described below. In the present embodiment, the same parts as those of the first embodiment are denoted by the same reference numerals, and repeated descriptions thereof are omitted.

The solid-state imaging element 1E of the present embodiment in FIG. 8 is different from the solid-state imaging element 1A of the first embodiment in that slits S7 constituting recessed portions 7 include multiple circular holes in plan view.

The slits S7 may each have a needed inside diameter 2r and may be disposed, for example, at equal intervals along the outer periphery of a cover glass 4 and an adhesive resin portion 9.

In other words, as illustrated in FIG. 8, a center distance between the slits S7 may be, for example, E1 in the longitudinal direction on the short side and may be E2 (E1=E2 or E1≠E2) in the lateral direction on the long side. The slits S7 are preferably disposed as close as possible to one another on the outer periphery of the cover glass 4 and the adhesive resin portion 9.

Specifically, when a distance between the outer periphery of the cover glass 4 and the adhesive resin portion 9 and the center position of the slit S7 is denoted as L2′, a distance L2 from the outer periphery of the cover glass 4 and the adhesive resin portion 9 to the closest portion of the slit S7 is expressed as follows: L2=L2′−r

Thus, in order to minimize the distance L2, the center position of the slit S7 may be located closer to the outer periphery of the cover glass 4 and the adhesive resin portion 9 or a radius r of the slit S7 may be slightly increased. In the latter case, a manufacturing method for forming the adjacent slits S7 can be more easily performed.

As in the first to fourth embodiments, the depth of the slit S7 is set without reaching the top of the wire 10. Moreover, the bottom of the slip S7 may be flattened as in the present embodiment, may be substantially U-shaped in cross section as illustrated in B of FIG. 4, or may be substantially V-shaped in cross section as illustrated in C of FIG. 4.

The slit S7 may be circular in plan view as in the present embodiment or may be shaped like, for example, a triangle, a quadrangle, a polygon having five or more corners, or an ellipse.

### <7. Solid-State Imaging Device According to Sixth Embodiment>

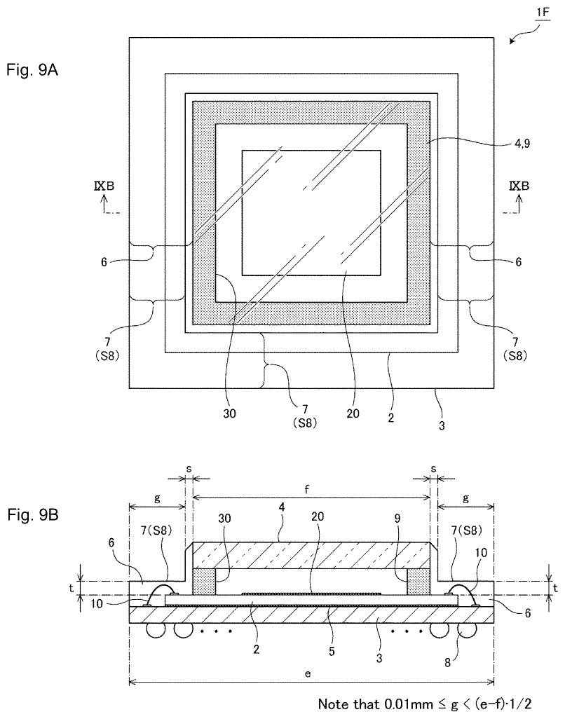

Referring to FIG. 9, a solid-state imaging device 1F according to a sixth embodiment of the present technique will be specifically described below. In the present embodiment, the same parts as those of the first embodiment are denoted by the same reference numerals, and repeated descriptions thereof are omitted.

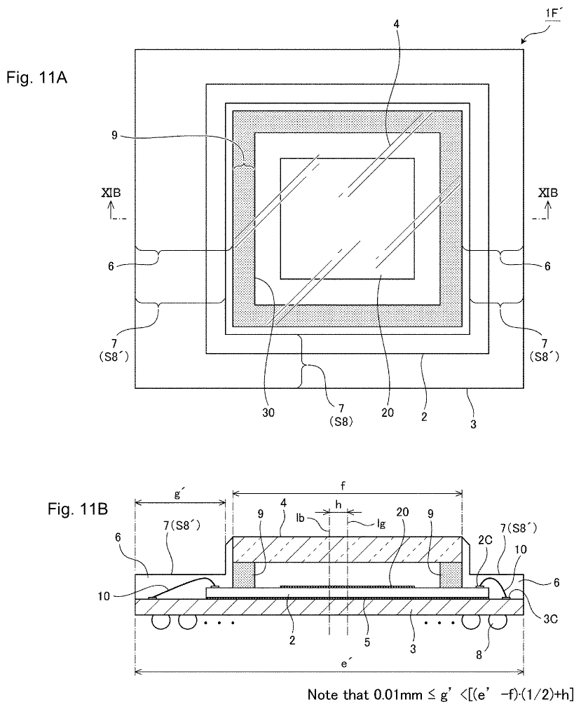

The solid-state imaging element 1F of the present embodiment in FIG. 9 is different from the solid-state imaging elements 1A to 1E of the first to fifth embodiments in that a recessed portion 7 is not shaped like a narrow groove and includes a step portion S8 that is a step opened to the outside with a thickness t in the longitudinal direction. In the solid-state imaging element 1F of the present embodiment, an image sensor 2 is symmetrically placed on a substrate 3. The structure is not particularly limited thereto. The image sensor 2 may be asymmetrically placed as illustrated in FIG. 11, which will be described later.

The step portion S8 is provided around the outer periphery of a cover glass 4 and an adhesive resin portion 9 integrated with the cover glass 4. The step portion S8 has a flat floor shape over the front side of a resin sealing portion 6, the floor shape extending to the outer surface of the solid-state imaging device 1F from an outer portion located at a necessary distance s from the outer periphery of the cover glass 4 and the adhesive resin portion 9 integrated with the cover glass 4. In other words, the outer portion of the resin sealing portion 6 is removed to form a flat floor shape that is substantially L-shaped in longitudinal section. Additionally, the step portion S8 is formed into a square shape in plan view outside the cover glass 4 and the adhesive resin portion 9 integrated with the cover glass 4.

Thus, according to the present embodiment, the step portion S8 is formed in this shape as the recessed portion 7, so that the outer periphery of the cover glass 4 and the adhesive resin portion 9 integrated with the cover glass 4 can be sealed with the resin sealing portion 6 having the minimum thickness t. In other words, the thickness t of the resin sealing portion 6 is considerably reduced as compared with those of the foregoing embodiments.

Moreover, according to the present embodiment, a difference in the coefficient of linear expansion is typically large between the cover glass 4 and the resin sealing portion 6. Thus, if large thermal fluctuations occur under the installation environment or the like, the resin sealing portion 6 has a larger coefficient of linear expansion than the cover glass 4 per unit length, accordingly. However, the thickness t of the resin sealing portion 6 is minimized in the direction of the cover glass 4. Hence, in this configuration, the net amount of linear expansion of this portion is not increased. This can effectively avoid problems such as a break and exfoliation on the cover glass 4. Such problems are caused by a thermal expansion force generated in the resin sealing portion 6 by a thermal stress.

Consequently, for example, if an environmental temperature decreases due to large thermal fluctuations, even when the resin sealing portion 6 has large thermal shrinkage caused by the large linear expansivity (in other words, a large coefficient of linear contraction) of the resin sealing portion 6, the effect of a shrinkage force on each portion of a substrate 3 decreases with a reduction in the thickness t of the resin sealing portion 6.

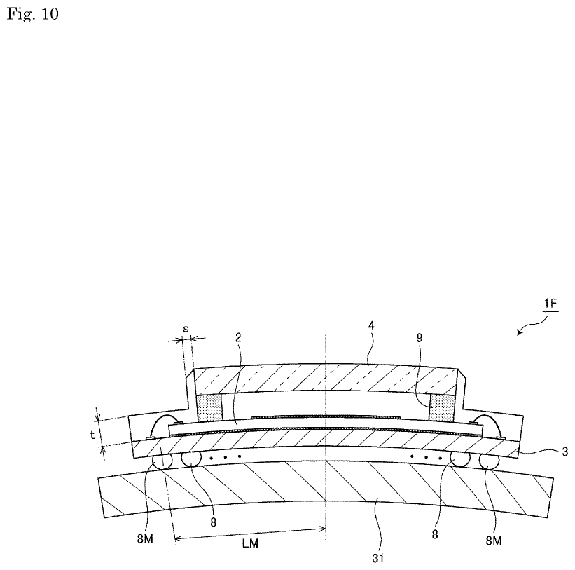

Thus, as illustrated in FIG. 10, also for a solder ball 8M that is remotest at a distance LM from a central portion among solder balls 8 of the substrate 3 and thus is expected to receive a large shrinkage force, a shrinkage force applied toward the substrate 3 by the resin sealing portion 6 is effectively suppressed. This can effectively suppress a peeling force applied to a connected portion between the solder ball 8M and a pad electrode or the like on an external substrate 3′. Hence, the peeling phenomenon of the solder ball 8M from the external substrate 3′ can be suppressed, thereby improving electrical reliability after packaging.

An underfill width g of the step portion S8 serving as the recessed portion 7 of the present embodiment is preferably, for example, 0.01 mm or more as a minimum width (minimum limit value). Thus, the range of the width of the step portion S8 is determined as follows:

$$0.01 \leq g < ( e - f ) / 2$$

where e is the overall length of the substrate, and
f is the overall length of the cover glass.

The recessed portion 7 is more easily formed than a narrow slit, leading to cost reduction.

In the solid-state imaging element 1F of the present embodiment, the image sensor 2 is symmetrically placed on the substrate 3. The structure is not particularly limited thereto. The image sensor 2 may be placed as illustrated in FIG. 11, which will be described later.

### <8. Modification Example of Solid-State Imaging Device According to Sixth Embodiment>

Referring to FIG. 11, a modification example of the solid-state imaging device 1F according to the sixth embodiment of the present technique will be described below.

In a solid-state imaging device 1F′ of the present embodiment, a cover glass 4 (and an image sensor 2) are displaced to the right relative to a substrate 3. Specifically, with respect to the central position of the substrate 3, the center position of the cover glass 4 (and the image sensor 3) is shifted to the right by a distance h. The center position of the substrate 3 is indicated by a center line lb, and the center position of the cover glass 4 is indicated by a center line lg.

In the solid-state imaging device 1F′ configured thus, an underfill width g of a step portion S8′ constituting a recessed portion 7 is 0.01 mm or more as a minimum width (minimum limit value) as in the sixth embodiment. The width is determined by the following range:

$$0.01 \leq g < [ ( e - f ) / 2 ] + h$$

where e is the overall length of the substrate,
f is the overall length of the cover glass, and
h is an amount of displacement between the center positions of the substrate and the cover glass.

Thus, according to the present embodiment, the layout and formation of the step portion S8′ can be designed with high flexibility according to the state of installation of the circuits of the respective solid-state imaging elements 1F′, achieving the effect of obtaining a flexible measure.

### <9. Solid-State Imaging Device According to Seventh Embodiment>

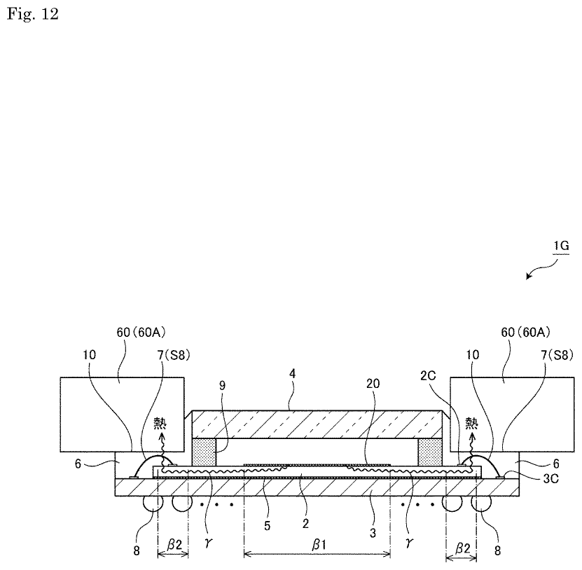

Referring to FIG. 12, a solid-state imaging device 1G according to a seventh embodiment of the present technique will be specifically described below. In the present embodiment, the same parts as those of the first to sixth embodiments are denoted by the same reference numerals, and repeated descriptions thereof are omitted.

In the solid-state imaging element 1G of the present embodiment in FIG. 12, a recessed portion 7 includes a step portion S8 as in the solid-state imaging element 1A of the sixth embodiment in FIG. 9. A heat radiation source 60 is fixed on the step portion S8.

For the heat radiation source 60 of the present embodiment, for example, materials having high thermal conductivity or materials having high thermal conductivity and thermal radiation (hereinafter these materials will be referred to as highly thermal conductive materials 60A) can be used. For example, copper and aluminum can be used as the highly thermal conductive materials 60A.

As the heat radiation source 60, a heat sink made of metals having an excellent heat transmission property, for example, aluminum (Al), iron (Fe), and copper (Cu) may be used. Furthermore, as the heat radiation source 60, forced cooling members such as a Peltier element may be used with a Peltier effect, in which heat is transferred by applying current to, for example, a bismuth tellurium semiconductor.

Thus, according to the present embodiment, even if a large amount of Joule heat or the like is generated in, for example, a region β1 of a pixel part 20 near the central portion of a front side 2A and a region β2 of a logic circuit, which is not illustrated, near the outer periphery of the front side 2A in, for example, an image sensor 2 that is particularly a circuit having an excellent heat generating property, the heat can be effectively moved to the highly thermal conductive material 60A through a heat path γ that is formed to reach the highly thermal conductive material 60A through the image sensor 2 and a resin sealing portion 6.

This can avoid the accumulation of Joule heat or the like in the resin sealing portion 6 and prevent the resin sealing portion 6 from causing large thermal expansion because the resin sealing portion 6 has a larger coefficient of linear expansion than a cover glass 4. Consequently, even if large thermal fluctuations occur under, for example, the installation environment of the solid-state imaging element 1G, the present embodiment can effectively avoid the exfoliation of the cover glass 4 from an adhesive resin portion 9 and a break on the cover glass 4. The exfoliation and break are caused by a thermal stress generated by the resin sealing portion 6 according to a difference in the coefficient of linear expansion between the cover glass 4 and the resin sealing portion 6.

Furthermore, according to the present embodiment, large fluctuations in resistance value according to a temperature change can be avoided, thereby achieving stable circuit operations and providing the solid-state imaging device 1G of high quality.

### <10. Solid-State Imaging Device According to Eighth Embodiment>

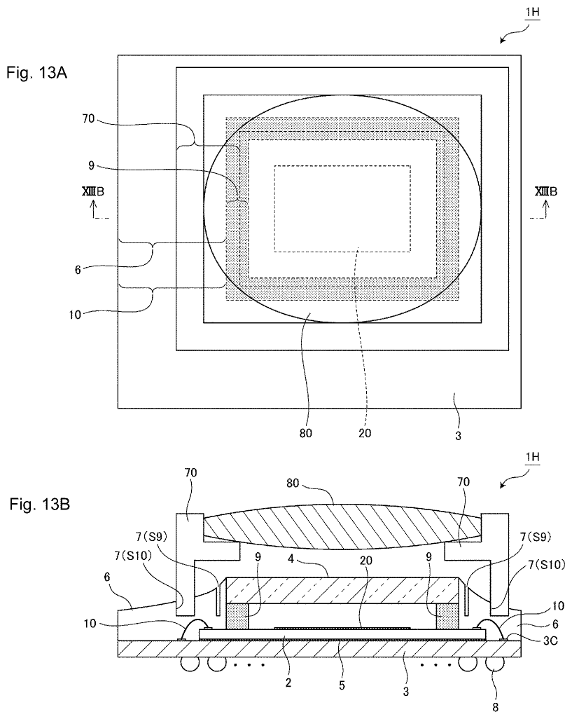

Referring to A and B in FIG. 13, a solid-state imaging device 1H according to an eight embodiment of the present technique will be specifically described below. In the present embodiment, the same parts as those of the first embodiment are denoted by the same reference numerals, and repeated descriptions thereof are omitted.

The solid-state imaging element 1H of the present embodiment in FIG. 13 is different from the solid-state imaging element 1A of the first embodiment in that recessed portions 7 are configured with a third slit S9 and a fourth slit S10 that are formed at two points on a resin sealing portion 6 and a lens holder 70 is provided for the fourth slit S10 formed outside the slit S9 on the resin sealing portion 6.

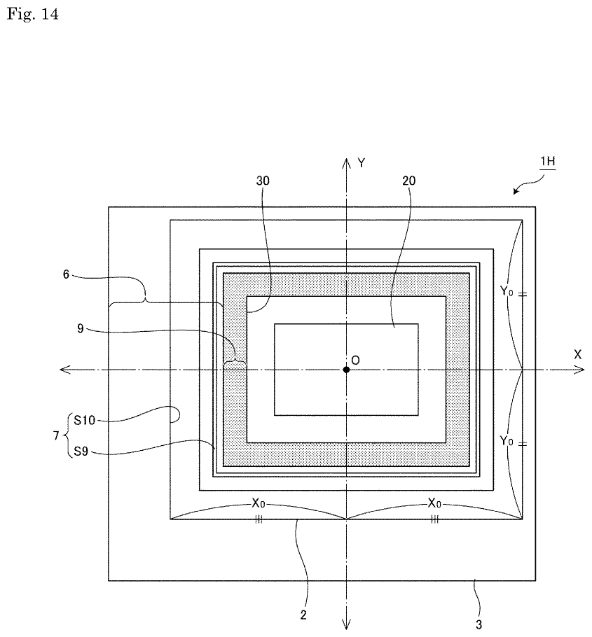

At least the fourth slit S10 is formed with high positioning accuracy with respect to pixels provided in a pixel part 20 (hereinafter may be referred to as “the fourth slit S10 is formed with respect to the pixels”). Specifically, as illustrated in FIG. 14, the solid-state imaging device 1H having an irregular layout configuration will be described below. For example, an image sensor 2 is shifted diagonally upward with respect to a substrate 3 because of the installation circuit and other specific circumstances.

In other words, when the fourth slit S10 is formed in this case, the fourth slit S10 is formed with respect to the pixels such that cartesian coordinates (X, Y) are set with an origin point O located at the center position of the pixel part 20 of the image sensor 2 instead of the center position of the substrate 3 and a layout relationship is set to match the center position of the fourth slit S10 to the origin point O of the pixel part 20. The third slit S9 of the present embodiment is similarly formed with respect to the pixels.

The lens holder 70 is fit and fixed to the fourth slit S10 having a larger width than the third slit S9. The fourth slit S10 is formed with high positioning accuracy with respect to the pixel part 20, so that the lens holder 70 is also configured and set such that the center position agrees with the origin point O at the center position of the pixel part 20.

Moreover, the lens holder 70 is configured to fix and hold a lens 80 and is made of proper materials that minimize expansion and shrinkage caused by thermal fluctuations.

Furthermore, the lens 80 held by the lens holder 70 is also fixed to the lens holder 70 with high positioning accuracy and is configured and set such that the optical axis agrees with the origin point at the center position of the pixel part 20.

Thus, according to the present embodiment, even if thermal fluctuations occur, the third slit S9 keeps a distance at least from the second slit S10, so that even if the resin sealing portion 6 causes thermal expansion or thermal shrinkage between the slits, the amount of expansion and shrinkage between the slits remains the same as long as a distance between the third slit S9 and the fourth slit S10 is kept in any parts in the vertical and horizontal directions. Thus, the center position of the lens holder 70 is not shifted from the center position of the pixel part 20.

Hence, even if large thermal fluctuations occur, the optical axis of the lens 80 is not shifted from the origin point O of the pixel part 20 unless the relative position of the lens 80 mounted in the lens holder 70 is changed with respect to the lens holder 70.

Moreover, according to the present embodiment, when the lens holder 70 is assembled after the third and fourth slits S9 and S10 are formed, alignment with the pixel part 20 can be completed only by fitting the slit into the recessed portion 7 of the fourth slit S10. Thus, the efficiency of the assembly operation is remarkably improved.

### <11. Solid-State Imaging Device According to Ninth Embodiment>

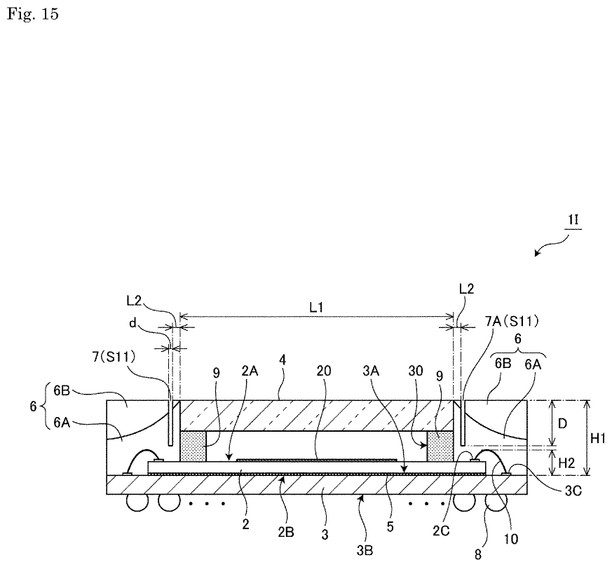

Referring to FIG. 15, a solid-state imaging device 1I according to a ninth embodiment of the present technique will be specifically described below. In the present embodiment, the same parts as those of the first embodiment are denoted by the same reference numerals, and repeated descriptions thereof are omitted.

The solid-state imaging element 1I of the present embodiment is different from the solid-state imaging element 1A of the first embodiment in that a resin sealing portion 6 includes two upper and lower layers. Specifically, the resin sealing portion 6 of the present embodiment includes a first resin sealing portion 6A having the same configuration as the resin sealing portion 6 of the first embodiment and a second resin sealing portion 6B that is stacked on the first resin sealing portion 6A and has a flat top surface.

The first resin sealing portion 6A is mounted to prevent the entry of moisture from the outside.

A recessed portion 7 of the present embodiment includes a deep slit S11 formed with a depth D such that the recessed portion 7 is vertically formed through the second resin sealing portion 6B into the first resin sealing portion 6A. The slit S11 is configured with the same slit depth in the first resin sealing portion 6A as the slit of the first embodiment without reaching the top of the wire 10.

Thus, according to the present embodiment, the slit S11 is formed on the flat top surface of the second resin sealing portion 6B instead of a tilted surface. This facilitates the formation of the slit S11 and leads to cost reduction.

### <12. Configuration Example of Electronic Device>

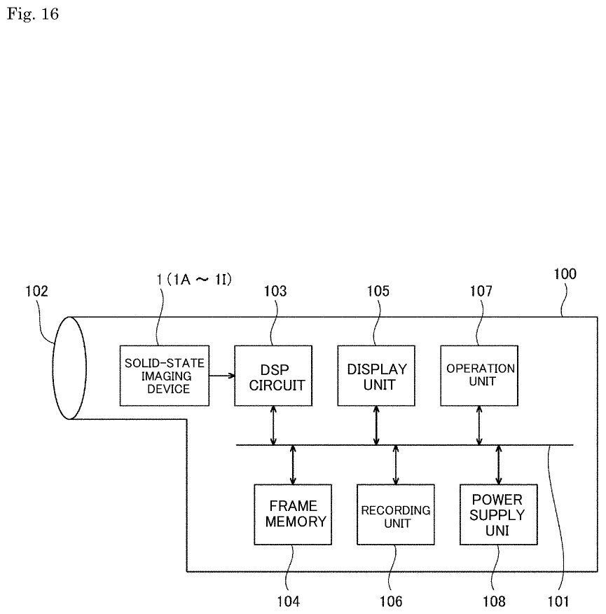

Referring to FIG. 16, an example of application of the solid-state imaging device according to the foregoing embodiment to an electronic device (e.g., an onboard imaging device) will be described below. An application example of the solid-state imaging device 1A according to the first embodiment will be described below. Other types of solid-state imaging elements are also applicable.

The solid-state imaging device 1A is applicable to a general electronic device in which a solid-state imaging element is used in an image capturing unit (a photoelectric conversion unit), for example, an imaging device such as a digital still camera or a video camera, a portable terminal device that has an imaging function, or a copy machine in which a solid-state imaging element is used in an image reading unit, in addition to an onboard imaging device or the like. The solid-state imaging element may be formed as a one-chip or may be formed as a module in which an imaging unit and a signal processing unit or an optical system are collectively packaged with an imaging function.

As illustrated in FIG. 16, an imaging device 100 as an electronic device includes an optical unit 102, the solid-state imaging device 1A, a digital signal processor (DSP) circuit 103 that is a camera signal processing circuit, a frame memory 104, a display unit 105, a recording unit 106, an operation unit 107, and a power supply unit 108. The DSP circuit 103, the frame memory 104, the display unit 105, the recording unit 106, the operation unit 107, and the power supply unit 108 are connected to one another via a bus line 101.

The optical unit 102 including a plurality of lenses captures incident light (image light) from a subject and forms an image on an imaging surface of the solid-state imaging device 1. The solid-state imaging device 1 converts the amount of incident light, which is formed into an image on the imaging surface by the optical unit 102, into an electric signal for each pixels and outputs the electric signal as a pixel signal.

The display unit 105 includes, for example, a panel-type display device such as a liquid crystal panel or an organic EL (Organic Electro Luminescence) panel and displays a moving image or a still image captured by the solid-state imaging device 1. The recording unit 106 records the moving image or the still image captured by the solid-state imaging device 1 in a recording medium, e.g., a hard disk or a semiconductor memory.

The operation unit 107 issues operator commands for various functions of the imaging device 100 on the basis of a user operation. The power supply unit 108 properly provides various power supplies as operation power supplies for the DSP circuit 103, the frame memory 104, the display unit 105, the recording unit 106, and the operation unit 107, to these units to be provided with the power supplies.

According to the imaging device 100 configured thus, even if a thermal stress is generated by thermal fluctuations caused by a difference in the coefficient of linear expansion between the cover glass 4 and the resin sealing portion 6 in the solid-state imaging device 1, the slit S1 is formed as the recessed portion 7 near the cover glass 4 of the resin sealing portion 6. In other words, even if the resin sealing portion 6 has a larger coefficient of thermal expansion (CTE) than the cover glass 4, the resin sealing portion 6 in contact with the cover glass 4 is divided by the slit S1 and thus among three factors that determine the amount of expansion, that is among the coefficient of linear expansion, a temperature change, and the length of a medium (resin sealing portion 6) that causes thermal expansion, the length of the medium, that is, a length from the slit S1 in the resin sealing portion 6 to the cover glass 4 can be reduced.

Thus, the amount of thermal expansion from the slit S1 to the cover glass 4 in the resin sealing portion 6 does not considerably increase, thereby avoiding problems caused by a thermal stress, for example, exfoliation or a break on the cover glass 4. Therefore, according to the imaging device 100 of the present embodiment, in the use for, for example, an onboard imaging device, these problems can be avoided in advance even if a temperature in a vehicle is considerably increased by the influence of an outside air temperature or the like, thereby obtaining the high-quality imaging device 100 with remarkably improved reliability and durability.

The description of the embodiment described above is an example of the present disclosure, and the present disclosure is not limited to the foregoing embodiment. For this reason, it is needless to say that various changes aside from the foregoing embodiment can be made according to the design and the like without departing from the technical idea of the present disclosure. In addition, the advantages described in the present specification are merely exemplary and not limited, and other advantages may be obtained. For example, the same is applied to thermal shrinkage as in the description of thermal expansion in the embodiment. The configurations of the embodiment and the modification examples can be combined as appropriate.

The present technique can be configured as follows:

(1)

A solid-state imaging device including: a solid-state imaging element that has a central portion in which an active region for photoelectrically converting incident light is formed, and a circumferential edge portion provided around the central portion;
a substrate that has a support on one side and an opening portion formed on the upper portion of the support, the support forming a surrounding space for storing the solid-state imaging element, the solid-state imaging element being mounted in a mounting region at the bottom of the space;
a cover glass with a circumferential edge portion on the undersurface of the cover glass, the circumferential edge portion being bonded to the support on one side of the substrate; and
a resin sealing portion that provides sealing around the cover glass;
wherein
the cover glass is integrally sealed by the resin sealing portion, and the resin sealing portion has, on the upper side of the resin sealing portion, a recessed portion toward the bottom of the resin sealing portion, the upper side including the vicinity of the cover glass.

(2)

The solid-state imaging element according to (1), further including a wire with one end making bonding connection to an electrode provided on the outer periphery of the side of the substrate to electrically connect the solid-state imaging element and the outside, and
the recessed portion is formed near the cover glass in a range of a depth without reaching the wire in the resin sealing portion.

(3)

The solid-state imaging device according to (1) or (2), wherein the recessed portion is formed around the vicinity of the circumference of the cover glass in the resin sealing portion.

(4)

The solid-state imaging device according to any one of (1) to (3), wherein the recessed portion is formed on at least one of four sides surrounding the cover glass.

(5)

The solid-state imaging device according to (4), wherein the recessed portion formed on the at least one side is shaped like a ribbon or a circle in at least one place.

(9)

The solid-state imaging device according to any one of (1) to (4), wherein the recessed portion is formed over an entire area other than the contact portion of the cover glass from the vicinity to the outer periphery of the cover glass.

(7)

The solid-state imaging element according to any one of (1) to (5), wherein the recessed portion is a groove having one of a substantially rectangular shape, a substantially U-shape, and a substantially V-shape in longitudinal section.

(8)

The solid-state imaging device according to any one of (1) to (5), wherein the recessed portion is formed around four sides surrounding the cover glass, and a lens holder that bears and supports a lens is fixed on an upper portion of the recessed portion.

(9)

The solid-state imaging device according to any one of (1) to (5), wherein the recessed portion is formed in at least multiple places, and
the recessed portion in at least one of the multiple places is continuously formed around the four sides surrounding the cover glass, and
a lens holder that bears and supports a lens is fixed on an upper portion of the recessed portion continuously formed around the four sides.

(10)

The solid-state imaging device according to any one of (1) to (4), wherein the recessed portion provided on at least one of the four sides surrounding the cover glass is provided with at least one of a highly thermal conductive member, a heat sink, and a Peltier element.

(11)

The solid-state imaging device according to any one of (1) to (9), wherein the resin sealing portion is provided with a second encapsulating resin of a different kind from the encapsulating resin in addition to the resin sealing portion while the second sealing resin covers the resin sealing portion, and
the recessed portion is formed with a depth reaching the encapsulating resin under the second encapsulating resin.

(12)

An electronic device including a solid-state imaging device including: a solid-state imaging element that has a central portion in which an active region for photoelectrically converting incident light is formed, and a circumferential edge portion provided around the central portion;
a substrate that has a support on one side and an opening portion formed on the upper portion of the support, the support forming a surrounding space for storing the solid-state imaging element, the solid-state imaging element being mounted in a mounting region at the bottom of the space;
a wire with one end making bonding connection to an electrode provided on the outer periphery of the side of the substrate to electrically connect the solid-state imaging element and the outside, and
a cover glass having an outside shape like one of a rectangle, a square, and a circle with a circumferential edge portion on the undersurface of the cover glass, the circumferential edge portion being bonded to one side of the substrate; and
a resin sealing portion that provides sealing around the cover glass;
wherein
the cover glass is integrally sealed for the wire with the encapsulating resin, and
the encapsulating resin has a recessed portion on the upper side of the encapsulating resin in a range of a depth without reaching the wire, the upper side including the vicinity of the cover glass.

### REFERENCE SIGNS LIST

1A to 1I, 1F′ Solid-state imaging device
2 Image sensor (Solid-state imaging element)
2A Front side
2B Back side
2C Pad electrode
20 Pixel part
3 Substrate
3′ External substrate
3A Front side
3B Back side
3C Pad electrode
30 Opening portion
30A Cavity (Space)
4 Cover glass
5 Die-bonding material
6 Resin sealing portion
6A First resin sealing portion
6B Second resin sealing portion
7 Recessed portion
8 Solder ball
8M Remotest solder ball
9 Adhesive resin portion (Support)
10 Wire
50 Mold frame
50A Fitting hole
50B Cavity
50C Protrusion
60 Heat radiation source
60A Highly thermal conductive material
70 Lens holder
80 Imaging lens
100 Imaging device
101 Bus line
102 Optical unit
103 DSP (Digital Signal Processor) circuit
104 Frame memory
105 Display unit
106 Recording unit
107 Operation unit
108 Power supply unit
101 Bus line
D Maximum depth of slit
H₁ Length from front side of substrate to top surface of cover glass
H₂ Length from front side of substrate to top of wire
lb Center line (Center position of substrate)
lg Center line (Center positions of cover glass and image sensor)
S1 to S7, S9 to S11 Slit
S′ Extended portion
S1′ Slit of long and narrow groove
S1″ Slit of long and narrow groove
S8 Step portion
a Length on major axis
a₀ Length of long side of cover glass and resin adhesive portion
b Length on minor axis
b₀ Length of short side of cover glass and resin adhesive portion
d Thickness (Protrusion)
e Overall length of substrate
f Overall length of cover glass
g Underfill width g of step portion
h Amount of displacement between center positions of substrate and cover glass
2r Inside diameter of slit
s Thickness of step portion to cover glass
t Thickness of step portion in longitudinal direction
α₁ Coefficient of linear expansion of cover glass
α₂ Coefficient of linear expansion of encapsulating resin
α₃ Coefficient of linear expansion of resin paste of die-bonding material
β1 Region of pixel part
β2 Region of logic circuit
γ Heat path

1. A solid-state imaging device comprising: a solid-state imaging element that has a central portion in which an active region for photoelectrically converting incident light is formed, and a circumferential edge portion provided around the central portion;
a substrate that has a support on one side and an opening portion formed on an upper portion of the support, the support forming a surrounding space for storing the solid-state imaging element, the solid-state imaging element being mounted in a mounting region at a bottom of the space;
a cover glass with a circumferential edge portion on an undersurface of the cover glass, the circumferential edge portion being bonded to the support on one side of the substrate; and
a resin sealing portion that provides sealing around the cover glass,
wherein
the cover glass is integrally sealed by the resin sealing portion, and
the resin sealing portion has, on the upper side of the resin sealing portion, a recessed portion toward a bottom of the resin sealing portion, the upper side including a vicinity of the cover glass.

2. The solid-state imaging element according to claim 1, further comprising a wire with one end making bonding connection to an electrode provided on an outer periphery of a side of the substrate to electrically connect the solid-state imaging element and outside, and
the recessed portion is formed near the cover glass in a range of a depth without reaching the wire in the resin sealing portion.

3. The solid-state imaging device according to claim 1, wherein the recessed portion is formed around a vicinity of a circumference of the cover glass in the resin sealing portion.

4. The solid-state imaging device according to claim 1, wherein the recessed portion is formed on at least one of four sides surrounding the cover glass.

5. The solid-state imaging device according to claim 4, wherein the recessed portion formed on the at least one side is shaped like a ribbon or a circle in at least one place.

6. The solid-state imaging device according to claim 1, wherein the recessed portion is formed over an entire area other than a contact portion of the cover glass from the vicinity to an outer periphery of the cover glass.

7. The solid-state imaging element according to claim 1, wherein the recessed portion is a groove having one of a substantially rectangular shape, a substantially U-shape, and a substantially V-shape in longitudinal section.

8. The solid-state imaging device according to claim 1, wherein the recessed portion is formed around four sides surrounding the cover glass, and
a lens holder that bears and supports a lens is fixed on an upper portion of the recessed portion.

9. The solid-state imaging device according to claim 1, wherein the recessed portion is formed in at least multiple places, and
the recessed portion in at least one of the multiple places is continuously formed around four sides surrounding the cover glass, and
a lens holder that bears and supports a lens is fixed on an upper portion of the recessed portion continuously formed around the four sides.

10. The solid-state imaging device according to claim 1, wherein the recessed portion provided on at least one of the four sides surrounding the cover glass is provided with at least one of a highly thermal conductive member, a heat sink, and a Peltier element.

11. The solid-state imaging device according to claim 1, wherein the resin sealing portion is provided with a second encapsulating resin of a different kind from the encapsulating resin in addition to the resin sealing portion while the second sealing resin covers the resin sealing portion, and
the recessed portion is formed with a depth reaching the encapsulating resin under the second encapsulating resin.

12. An electronic device comprising a solid-state imaging device including: a solid-state imaging element that has a central portion in which an active region for photoelectrically converting incident light is formed, and a circumferential edge portion provided around the central portion;
a substrate that has a support on one side and an opening portion formed on an upper portion of the support, the support forming a surrounding space for storing the solid-state imaging element, the solid-state imaging element being mounted in a mounting region at a bottom of the space;
a wire with one end making bonding connection to an electrode provided on an outer periphery of a side of the substrate to electrically connect the solid-state imaging element and outside, and
a cover glass having an outside shape like one of a rectangle, a square, and a circle with a circumferential edge portion on an undersurface of the cover glass, the circumferential edge portion being bonded to one side of the substrate; and
a resin sealing portion that provides sealing around the cover glass;
wherein
the cover glass is integrally sealed for the wire with the encapsulating resin, and the encapsulating resin has a recessed portion on an upper side of the encapsulating resin in a range of a depth without reaching the wire, the upper side including a vicinity of the cover glass.
